(19) United States
(12) Patent Application Publication
(10) Pub. No.: US 2006/0221750 A1
(43) Pub. Date: Oct. 5, 2006

(54) Output power modification methods and apparatuses for mobile communication devices

(75) Inventors: En-Tai Kuo, Kaohsiung County (TW); Liang-Fang Chen, Tainan City (TW); Kuo-Lung Huang, Taoyuan County (TW)

Correspondence Address: BIRCH STEWART KOLASCH & BIRCH, PO BOX 747, FALLS CHURCH, VA, 22040-0747, US

(73) Assignee: BENQ CORPORATION, Taoyuan (TW)

(21) Appl. No.: 11/358,009

(22) Filed: Feb. 22, 2006

(30) Foreign Application Priority Data
Feb. 23, 2005 (TW) 94105397

(51) Int. Cl. G11C 5/14

(52) U.S. Cl. 365/226

(57) ABSTRACT

Output power modification methods and apparatuses for mobile communication devices. The inventive apparatus comprises a receiver, a memory device, a calculation unit, and a translator. The receiver receives transmission channels and transmission power levels from a base station. The memory device stores scaling factors and delta scaling factors corresponding to reference channels and reference power levels. The calculation unit calculates digital control values according to scaling factors and delta scaling factors from the memory device, and the transmission channels and transmission power levels. The translator translates the digital control values to voltage values for controlling transmission power of the mobile communication devices.

### BACKGROUND

The invention relates to output power modification methods and apparatuses for mobile communication devices, and in particular to adjusting output power of a mobile communication device by estimating a required output power using an interpolation method.

Output power is critical for transmitters, and changes according to communication range. ETSI (European Telecommunication Standard Institution) Specification GSM 05:05 section 4.1.1 details the requirements for the absolute output power of a class 4 mobile communication device at different power control levels. GSM systems use dynamic power control to ensure that each communication connection is maintained using minimum power.

To achieve a PCL (Power Control Level), a calibration is done during the cellular phone manufacturing process to map a measured output RF power level to a digital control value, which is typically stored in the Digital Signal Processor (DSP) memory of the handset. The DSP drives a digital-to-analog converter (DAC), which creates an analog voltage waveform that ultimately shapes power amplifier RF ramping. The calibration involves the construction of table of calibration factors for power levels and communication frequency.

### SUMMARY

The present invention provides an output power modification method for a mobile communication system. The mobile communication system comprises a mobile communication device and a base station. The base station selects a transmission channel from a plurality of transmission channels. The base station further establishes a connection with the mobile communication device using a transmission power level at the selected transmission channel. The transmission channels comprise a reference channel. The selected transmission channel and the transmission power level are received from the base station. A digital control value is determined using a plurality of scaling factors corresponding to a plurality of power levels at the reference channel. A delta scaling factor corresponding to the reference channel and the transmission channel is used in a reference power level according to the transmission channel and the transmission power level. The digital control value is converted to a voltage value. The transmission power for the mobile communication device is determined according to the voltage value.

Also provided is a mobile communication device capable of calibrating output power. The mobile communication device connects with a base station using any of a plurality of transmission channels and transmits data thereby. The mobile communication device comprises a receiver, a memory, a calculation unit, and a translator. The receiver receives a transmission channel and a transmission power level from the base station. The memory stores a plurality of scaling factors and delta scaling factors, wherein the scaling factors correspond to a plurality of power levels used when transmitting at the reference channel, and the delta scaling factors correspond to difference between the scaling factors of the reference channel and the transmission channels at a reference power level. The calculation unit determines a digital control value according to the transmission channel and transmission power level received from the receiver and the delta scaling factor and scaling factor retrieved from the memory. The translator converts the digital control value to a voltage value for controlling the transmission power used by the mobile communication device.

### DESCRIPTION OF THE DRAWINGS

The invention can be more fully understood by reading the subsequent detailed description and examples with references made to the accompanying drawings, wherein:

FIG. 1 is a schematic view of an embodiment of a mobile communication device;

FIGS. 2a and 2b illustrate an embodiment of a coordinate system used for determining a digital control value for calibrating output power; and

FIG. 3 illustrates an embodiment of the relationship between the slope and the voltage value.

### DETAILED DESCRIPTION

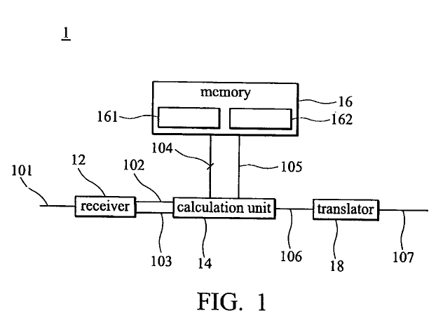

The invention will now be described with reference to FIGS. 1 through 3, which generally relate to mobile communication.

In the following detailed description, reference is made to the accompanying drawings which form a part hereof, and in which is shown by way of illustration of specific embodiments. These embodiments are described in sufficient detail to enable those skilled in the art to practice the invention, and it is to be understood that other embodiments may be utilized and that structural, logical and electrical changes may be made without departing from the spirit and scope of the present invention. The following detailed description is, therefore, not to be taken in a limiting sense. The leading digit(s) of reference numbers appearing in the figures corresponds to the Figure number, with the exception that the same reference number is used throughout to refer to an identical component which appears in multiple figures.

FIG. 1 is a schematic view of an embodiment of a mobile communication device. A mobile communication device 1 comprises a receiver 12, a calculation unit 14, memory 16, and a converter 18. The receiver 12 receives signals 101 at an antenna, receives a transmission channel 102 and a transmission power level 103 from a base station, and transmits transmission channel 102 and transmission power level 103 to calculation unit 14. The memory 16 stores tables 161 and 162. Table 161 stores a plurality of scaling factors corresponding to a plurality of power levels when transmitting at the reference channel. Table 162 stores scaling factor differences corresponding to the reference channel and the other transmission channels at a reference power level. Typically, the described reference channel is a middle channel of all usable transmission channels, and the scaling factor is a digital counting unit. After receiving transmission channel 102 and transmission power level 103, the calculation unit 14 retrieves corresponding scaling factor 104 and scaling factor difference 105 from memory 16, and determines a digital control value 106 accordingly. The converter 18 converts the digital control value 106 to a voltage value 107 for controlling the transmission power used by the mobile communication device 1.

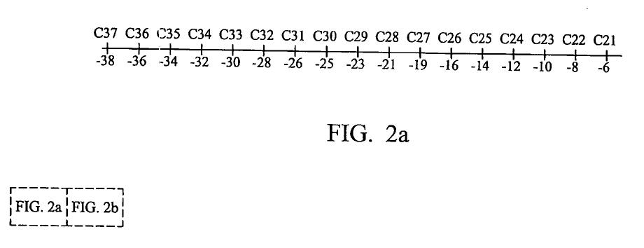

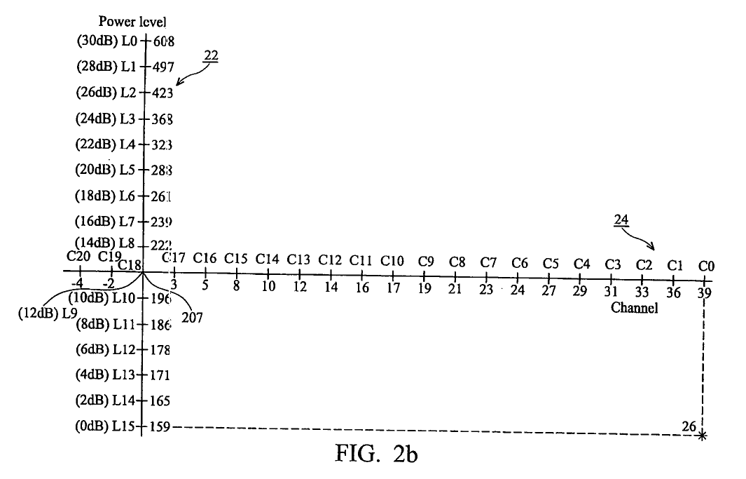

FIGS. 2a and 2b illustrate an embodiment of a coordinate system used for determining a digital control value for calibrating output power. The coordinate system comprises an X-axis and a Y-axis. The X-axis comprises X-coordinates specifying scaling factor differences stored in table 162. The Y-axis comprises Y-coordinates specifying scaling factors stored in table 161. According to the invention, scaling factors corresponding to coordinates in the coordinate system may be determined thereby. The coordinates of the coordinate system are determined according to measurements obtained from 38 transmission channels (C0˜C37) at about 1800 MHz in GSM system. In the GSM system, each transmission channel has a bandwidth about 200 KHz, and each channel provides voice transmission services to at most 8 clients. Referring to FIGS. 2a and 2b, the Y-axis comprises power levels L15˜L0, the difference between two adjacent power levels is 2 dB. Scaling factors corresponding to the power levels are measured during manufacture of a mobile communication device, wherein signals are transmitted at a preset reference channel 22 (channel C18) corresponding to each of the power levels. Referring to FIGS. 2a and 2b, the X-axis comprises transmission channels C0˜C37. Scaling factor differences corresponding to the transmission channels are measured when transmitting signals at a preset reference power level 24 (power level L9) corresponding to each of the transmission channels.

The calculation unit 14 receives transmission channel 102 and transmission power level 103, retrieves corresponding scaling factor 104 and scaling factor difference 105, and determines a digital control value 106 accordingly. The digital control value is determined according to the following equation:

$${S}_{cL ( n )} = {S}_{RL ( n )} + {Df}_{RLf} [ \frac{{S}_{RL ( n - 1 )} - {S}_{RL ( n )}}{{S}_{RL ( R - 1 )} - {S}_{RL ( R )}} ] \qquad ( equation 1 )$$

S_{cL(n)} is a digital control value, specifying a scaling factor corresponding to a transmission power level (level n) at a transmission channel. S_{RL(n)} is a scaling factor (a first scaling factor) corresponding to a transmission power level n at the reference transmission channel. S_{RL(n-1)} is a scaling factor (a second scaling factor) corresponding to a transmission power level n−1, which is adjacent to the power level of S_{RL(n)}. Similarly, S_{RL(R)} is a scaling factor (a third scaling factor) corresponding to reference transmission power level R at reference transmission channel. Similarly, S_{RL(R-1)} is a scaling factor (a fourth scaling factor) corresponding to transmission power level R−1, which is adjacent to the power level of S_{RL(R)}. Df_{RLf} is a scaling factor difference between the reference transmission channel and a transmission channel at the reference power level.

Using FIGS. 2a and 2b as an example, a channel C18 is used as a reference transmission channel 22, and power level L9 is used as a reference power level 24. When a mobile communication device sends a request to a base station for establishing a voice communication, the base station assigns a transmission channel thereto. According to this embodiment, a channel C0 is assigned by the base station. Additionally, the base station assigns a transmission power level to the mobile communication device according to the signal strength amd diminution level from the mobile communication device. In this embodiment, power level L15 is assigned to the mobile communication device. The mobile communication device determines a digital control value 26 according to the assigned transmission channel C0 and power level L15, and accordingly transmits signals at a proper power level. The mobile communication device retrieves a scaling factor difference corresponding to transmission channel C0, and retrieves a scaling factor corresponding to power level L15, and determines a digital control value S_{cL(15)} as the following equation 2.

$${S}_{cL ( 15 )} = {S}_{RL ( 15 )} + {Df}_{RLf} [ \frac{{S}_{RL ( 14 )} - {S}_{RL ( 15 )}}{{S}_{RL ( 8 )} - {S}_{RL ( 9 )}} ] \qquad ( equation 2 )$$

Accordingly,

$${S}_{cL ( 15 )} = 159 + 39 [ \frac{165 - 159}{222 - 207} ] = 174.6$$

The digital control value 174.6 is then converted to a voltage value by a converter of the mobile communication device. The voltage value is then used for controlling transmission power of the mobile communication device.

According to this embodiment, the mobile communication device uses a 10-bit digital control value for calibrating a 2.2-voltage range. The conversion from the digital control value to the voltage ΔV_{apc} is performed according to the following equation:

$$Δ {V}_{apc} = {S}_{cL ( n )} ( \frac{2.2}{{2}^{10}} ) = {S}_{cL ( n )} ( \frac{2.2}{1024} ) \qquad ( equation 3 )$$

The voltage value converted from the digital control value (174.6) is 0.375.

According to equation 1, the ratio of (S_{RL(n-1)}-S_{RL(n)}) to (S_{RL(n-1)}-S_{RL(n)}) is determined according to a ratio of scaling factor variations thereof, which can be specified as follows:

$$\frac{{S}_{RL ( n - 1 )} - {S}_{RL ( n )}}{{S}_{RL ( R - 1 )} - {S}_{RL ( R )}} = \frac{Δ sf ( L ( n - 1 ) - L ( n ) )}{Δ sf ( L ( R - 1 ) - L ( R ) )} \qquad ( equation 4 )$$

Ratio of a variation of power levels (ΔdBm) to a variation of voltage values (ΔV_{apc}) is referred to as a slope of these two parameters, which can be specified as follows:

$$slope = \frac{Δ dBm}{Δ {V}_{apc}} ⇒ Δ {V}_{apc} = \frac{Δ dBm}{slope} \qquad ( equation 5 )$$

The scaling factor is a digital control value, and can be converted to a voltage value according to the equation 3.

$$Δ sf = Δ {V}_{apc} \frac{1024}{2.2} \qquad ( equation 6 )$$

According to equations 5 and 6, the scaling factor can be determined as follows:

$$Δ sf = \frac{Δ dBm}{slope} \times \frac{1024}{2.2} \qquad ( equation 7 )$$

Combining equations 7 and 4, an equation 8 can be further determined:

$$\frac{{S}_{RL ( n - 1 )} - {S}_{RL ( n )}}{{S}_{RL ( R - 1 )} - {S}_{RL ( R )}} = \frac{\frac{Δ dBm ( L ( n - 1 ) - L ( n ) )}{slope ( L ( n - 1 ) - L ( n ) )}}{\frac{Δ dBm ( L ( R - 1 ) - L ( R ) )}{slope ( L ( R - 1 ) - L ( R ) )}} = \frac{Δ dBm ( L ( n - 1 ) - L ( n ) )}{Δ dBm ( L ( R - 1 ) - L ( R ) )} \times \frac{slope ( L ( R - 1 ) - L ( R ) )}{slope ( L ( n - 1 ) - L ( n ) )} \qquad ( equation 8 )$$

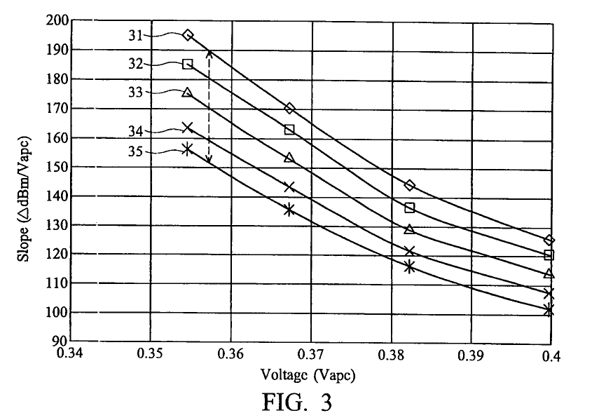

According to equation 8, if the slope curves for different transmission channels are similar for a power amplifier of a mobile communication device, an accurate scaling factor can be obtained using the described equations. FIG. 3 illustrates an embodiment of relationship between the slope and the voltage value.

Referring to FIG. 3, slope curves for transmission channels 31˜35 are illustrated, wherein Y-coordinates comprise slopes (ΔdBm/ΔV_{apc}), and X-coordinates comprise voltage values. The channel 33 is reference channel. The slope curves of channels 31˜35 are similar between 0.35V˜0.4V. The accuracy of scaling factors determined according to the described method depends on the similarity of the slope curves of different transmission channels. At a particular power level, the slopes of scaling factors are preferably similar.

When determining a reference power level, the difference between scaling factors of a reference channel and other channels at the reference power level is considered. It is preferred that the variation of scaling factor differences (Df_{RLf}) is the lowest, thus a lowest error ratio of the scaling factor differences may be obtained. The scaling factor differences (Df_{RLf}) can be determined according to an equation similar to equation 7, which is as follows:

$$Δ {Df}_{RLf} = \frac{Δ dBm}{slope} \times \frac{1024}{2.2} \qquad ( equation 9 )$$

ΔdBm specifies a difference between power multiples of a reference channel and a transmission channel at a reference power level, and the slope is the slope of the reference power level at the reference channel. According to equation 9, when a more proper reference power level is selected, a lower variation of scaling factor difference (Df_{RLf}) can be obtained. In other words, a power level which results in the lowest variation of scaling factor difference (ΔDf_{RLf}) is a most proper power level. There are two ways to obtain a lower scaling factor differences variation (ΔDf_{RLf}). One method is to lower ΔdBm, which is the differences of power multiples between reference power level and the standard power level, so that an accurate digital control value may be obtained. Another method comprises increasing the slope of a reference power level. Typically, a power level corresponding to larger slopes at every transmission channels may be selected as a reference power level.

While the invention has been described by way of example and in terms of several embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An output power calibration method for a mobile communication system, the mobile communication system comprising a mobile communication device and a base station, wherein the base station selects a transmission channel from a plurality of transmission channels, and establishes a connection with the mobile communication device using a transmission power level at the selected transmission channel, wherein the plurality of transmission channels comprise a reference channel, the method comprising:
receiving the selected transmission channel and the transmission power level from the base station;
determining a digital control value by using a plurality of scaling factors corresponding to a plurality of power levels at the reference channel, and by using a scaling factor difference corresponding to the reference channel and the transmission channel used in a reference power level according to the
transmission channel and the transmission power level;
converting the digital control value to a voltage value; and
determining the transmission power for the mobile communication device according to the voltage value.

2. The output power calibration method of claim 1, wherein the determination of the digital control value further comprises:
searching for first and second scaling factors corresponding to the transmission power level and a power level adjacent thereto at the reference channel;
searching for third and fourth scaling factors corresponding to the reference power level and a power level adjacent thereto at the reference channel;
determining a slope, wherein the slope is a ratio of a difference between the first and the second scaling factors to a difference between the third and fourth scaling factors; and
determining the digital control value by multiplying the slope by the difference of scaling factors between the reference channel and the transmission channel at the reference power level.

3. The output power calibration method of claim 1, wherein the voltage value is determined by multiplying a voltage range by a ratio of the digital control value to a control resolution value, wherein the control resolution value is for determining the accuracy of the conversion of the digital control value to the voltage value.

4. The output power modification method of claim 1, wherein the reference power level corresponds to the lowest scaling factor difference, wherein the lowest scaling factor difference is the lowest difference of two scaling factors among the reference channel and other transmission channels.

5. The output power modification method of claim 4, further comprising decreasing the scaling factor difference.

6. The output power modification method of claim 5, further comprising decreasing a power difference of a power multiple between the reference power and a standard power.

7. The output power modification method of claim 5, further comprising increasing a slope of the reference channel to the reference power level.

8. A mobile communication device, capable of calibrating output power, connecting with a base station by at least one of a plurality of transmission channels, the mobile communication device comprising:
a receiver for receiving a transmission channel and a transmission power level from the base station;
a memory, for storing scaling factors and scaling factor differences, wherein the scaling factors correspond to a plurality of power levels at a reference channel, and the scaling factor differences correspond to the reference channel and the other transmission channels at a reference power level;
a calculation unit for determining a digital control value according to the transmission channel, the transmission power level, one of the scaling factor differences, and one of the scaling factors retrieved from the memory; and
a converter for converting the digital control value to a voltage value for controlling the transmission power of the mobile communication device.

9. The mobile communication device of claim 8, wherein the calculation unit further performs the steps of:
searching for first and second scaling factors corresponding to the transmission power level and a power level adjacent thereto at the reference channel;
searching for third and fourth scaling factors corresponding to the reference power level and a power level adjacent thereto at the reference channel;
determining a slope, wherein the slope is a ratio of a difference between the first and the second scaling factors to a difference between the third and fourth scaling factors; and
determining the digital control value by multiplying the slope by the difference of scaling factors between the reference channel and the transmission channel at the reference power level.

10. The mobile communication device of claim 8, wherein the converter determines the voltage value by multiplying a voltage range by a ratio of the digital control value to a control resolution value.
